(19) United States
(12) Patent Application Publication
(10) Pub. No.: US 2015/0087144 A1
(43) Pub. Date: Mar. 26, 2015

(54) APPARATUS AND METHOD OF MANUFACTURING METAL GATE SEMICONDUCTOR DEVICE

(71) Applicant: TAIWAN SEMICONDUCTOR MANUFACTURING COMPANY LTD., Hsinchu (TW)

(72) Inventors: CHI-JEN LIU, TAIPEI CITY (TW); CHIH-CHUNG CHANG, NANTOU COUNTY (TW); LI-CHIEH WU, HSINCHU CITY (TW); SHICH-CHANG SUEN, HSINCHU CITY (TW); LIANG-GUANG CHEN, HSINCHU CITY (TW)

(73) Assignee: TAIWAN SEMICONDUCTOR MANUFACTURING COMPANY LTD., Hsinchu (TW)

(21) Appl. No.: 14/038,091

(22) Filed: Sep. 26, 2013

(51) Int. Cl. H01L 29/423; H01L 21/02; H01L 21/67

(52) U.S. Cl. CPC H01L 29/42368; H01L 21/67017; H01L 21/02041
USPC 438/595; 156/345.12

(57) ABSTRACT

A method of manufacturing a semiconductor device includes providing a semiconductor substrate and forming a structure over the semiconductor substrate. The structure includes a sacrificial dielectric on the semiconductor substrate and a dummy gate over the sacrificial dielectric. The method further includes removing the dummy gate and the sacrificial dielectric from the structure thereby forming a trench. The method further includes filling a metal layer into the trench and covering over a top surface of an inter layer dielectric (ILD). The method also includes performing a chemical mechanical polishing (CMP) to expose the top surface of the ILD and heating the top surface of the ILD. Moreover, the method includes forming an etch stop layer on the top surface of the ILD.

### FIELD

The present disclosure relates to apparatus and method of manufacturing metal gate semiconductor device.

### BACKGROUND

The semiconductor integrated circuit (IC) industry has experienced rapid growth. As the dimensions of transistors decrease, the thickness of the gate oxide must be reduced to maintain performance with the decreased gate length. However, in order to reduce gate leakage, high dielectric constant (high-k) gate insulator layers are used which allow greater physical thicknesses while maintaining the same effective thickness as would be provided by a typical gate oxide used in larger technology nodes.

Additionally, as technology nodes shrink, in some IC designs, there has been a desire to replace the typically polysilicon gate electrode with a metal gate (MG) electrode to improve device performance with the decreased feature sizes. One process of forming the MG electrode is termed “gate last” process in which the final metal gate electrode is fabricated “last” which allows for reduced number of subsequent processes, including high temperature processing, that must be performed after formation of the gate.

However, problems arise when integrating a high-k/metal gate feature in a CMOS technology process flow due to various factors such as incompatibility of materials, complex processes, and thermal budgets. Therefore, for these advances to be realized, similar developments in IC processing and manufacturing are needed.

### BRIEF DESCRIPTION OF THE DRAWINGS

Aspects of the present disclosure are described with reference to the accompanying figures. It is emphasized that, in accordance with the standard practice in the industry, various features are not drawn to scale. In fact, the dimensions of the various features may be arbitrarily increased or reduced for clarity of discussion.

FIG. 1 is a flowchart of a method for fabricating a semiconductor device with a high-k metal gate according to various aspects of the present disclosure.

FIGS. 2A to 2M are cross-sectional views of a semiconductor device at various stages of fabrication according to the method of FIG. 1.

FIG. 3 is a semiconductor wafer chemical mechanical polishing apparatus for manufacturing a semiconductor device with a high-k metal gate in accordance with some embodiments of the present disclosure.

### DETAILED DESCRIPTION OF THE INVENTION

It is understood that the following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

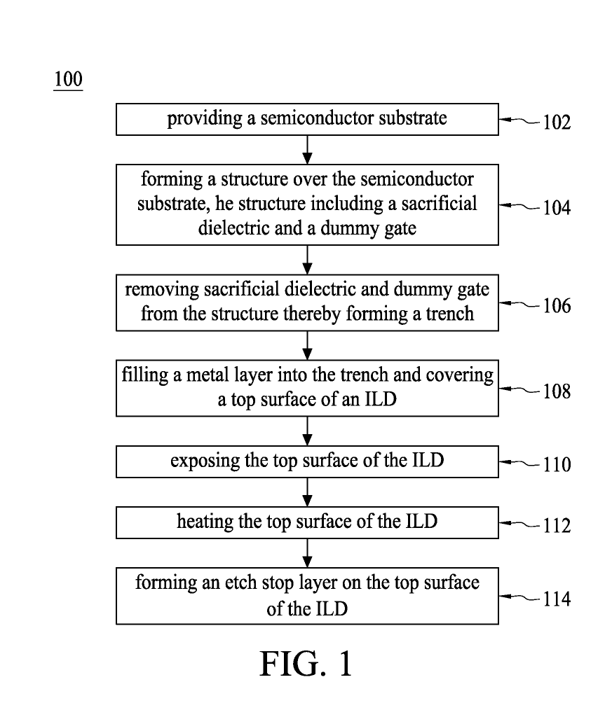

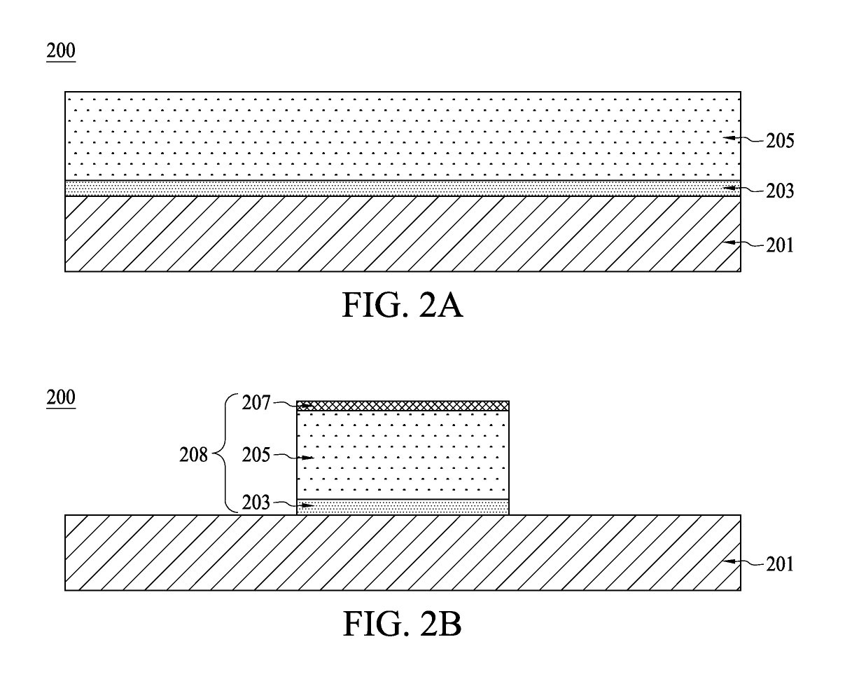

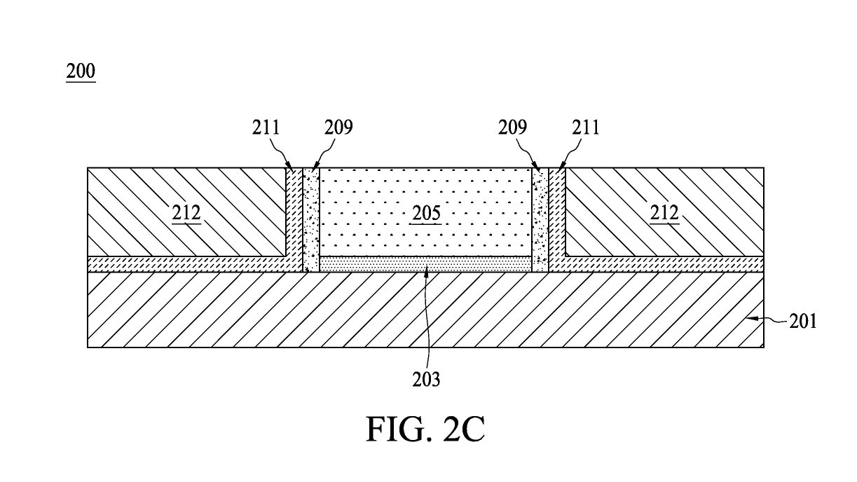

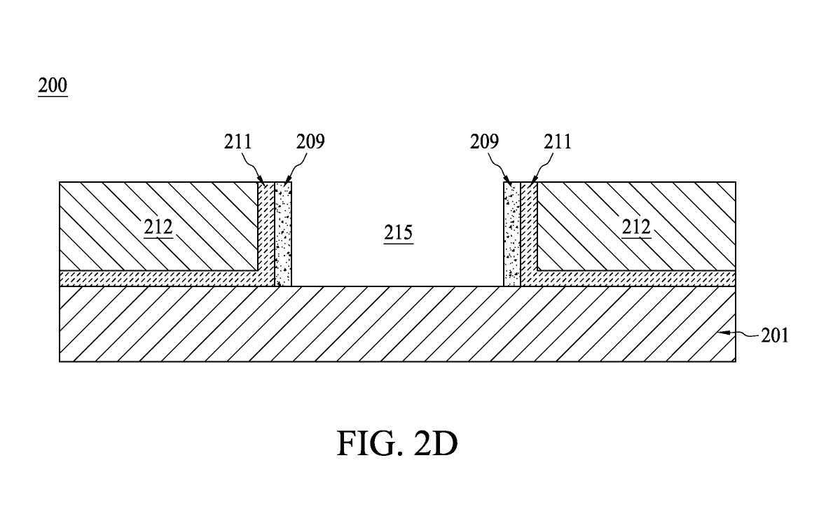

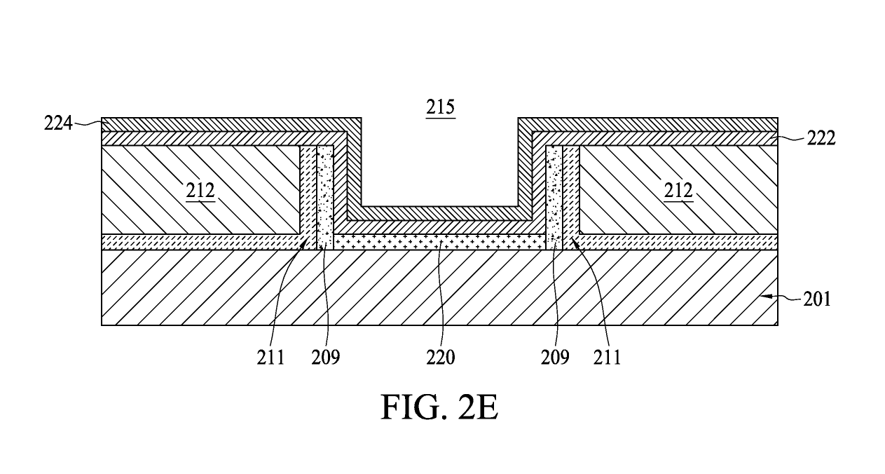

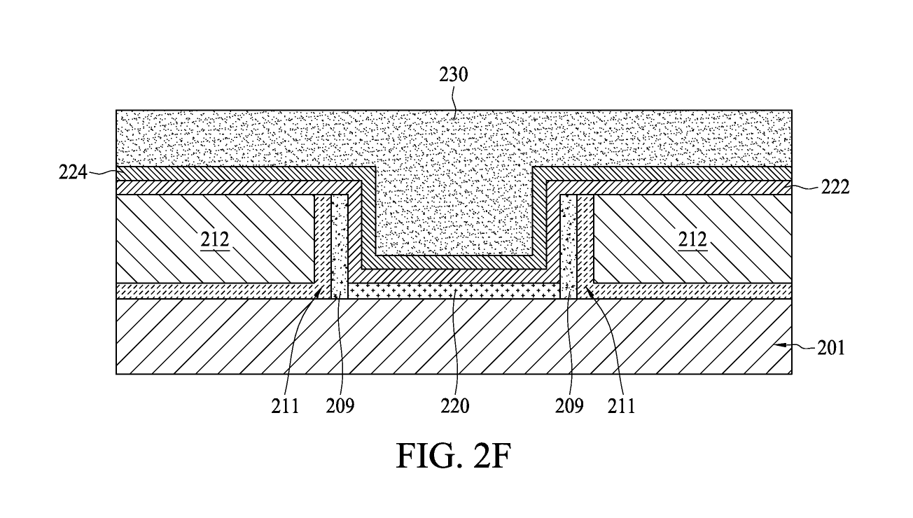

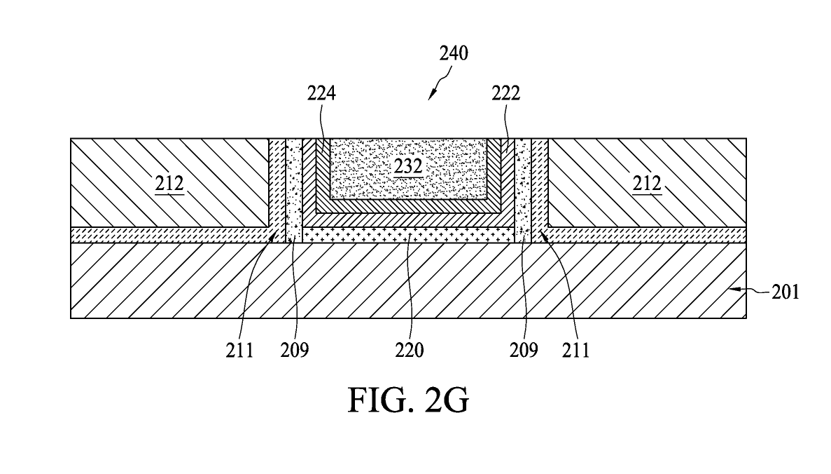

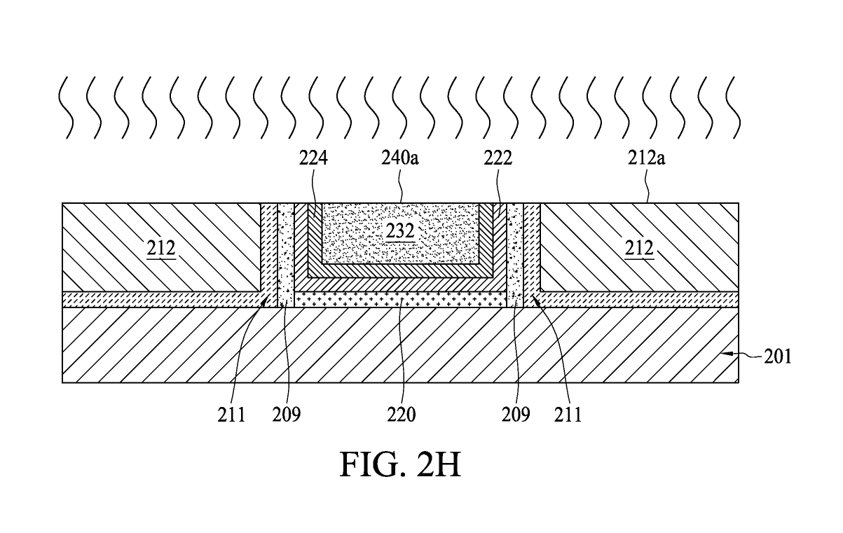

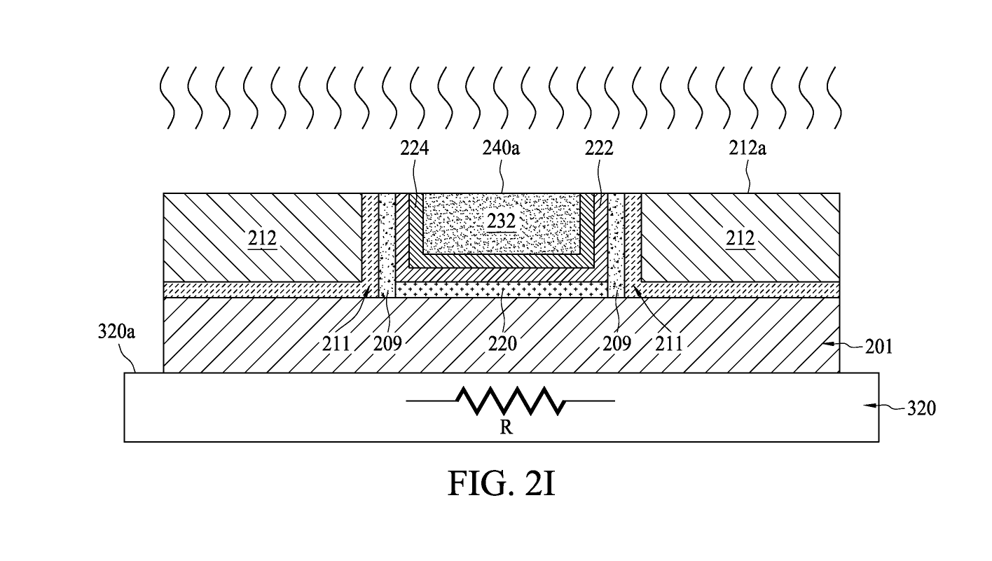

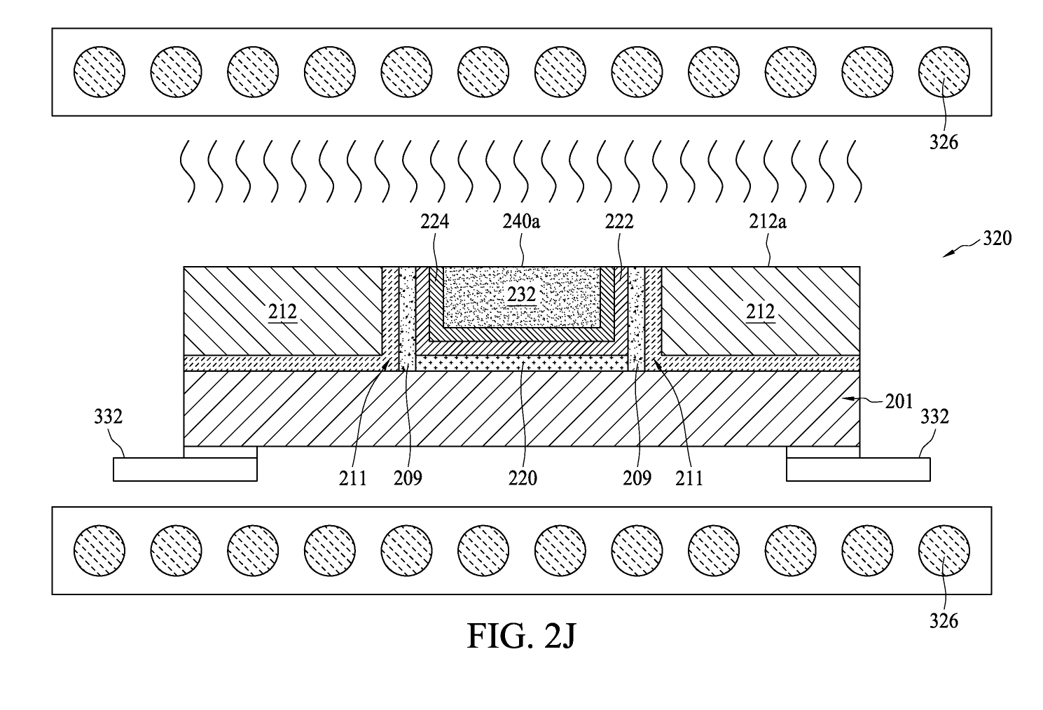

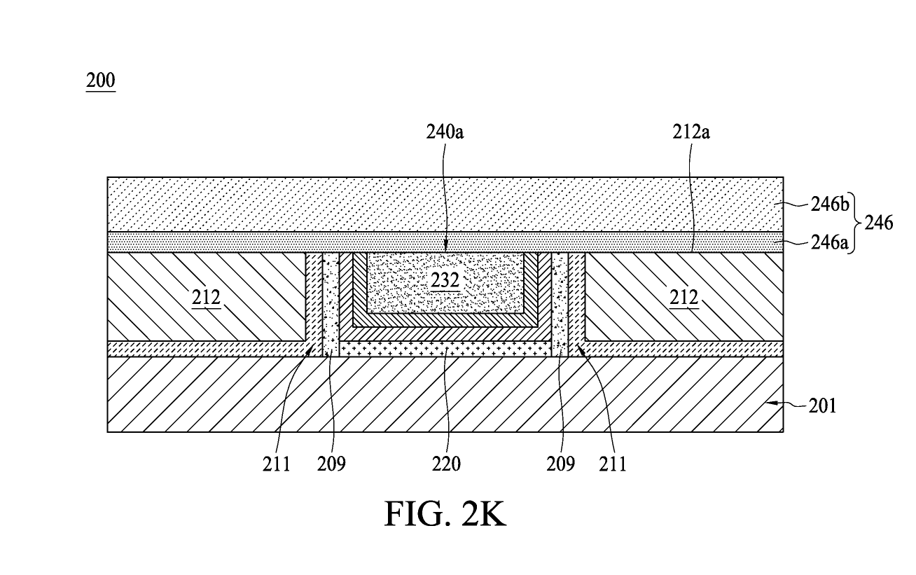

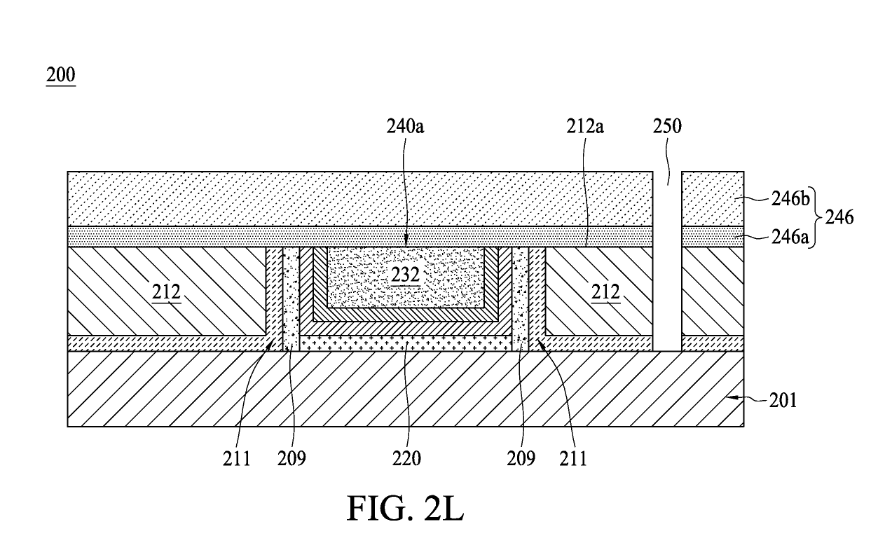

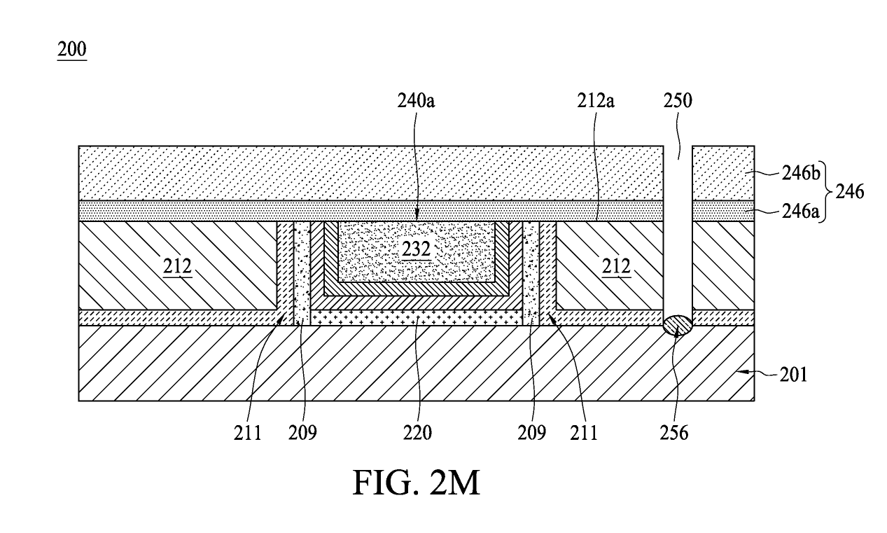

Referring to FIG. 1, illustrated is a flowchart of a method 100 for fabricating a semiconductor device with a high-k metal gate according to various aspects of the present disclosure. Referring also to FIGS. 2A to 2M, illustrated are cross-sectional views of a semiconductor device 200 at various stages of fabrication according to the method 100 of FIG. 1. It should be noted that part of the semiconductor device 200 may be fabricated with a CMOS process flow. Accordingly, it is understood that additional processes may be provided before, during, and after the method 100 of FIG. 1. It is understood that FIGS. 2A to 2M have been simplified for the clarity to better understand the inventive concepts of the present disclosure. The semiconductor device 200 may be fabricated in a high-k dielectric/metal gate last process (also referred to as a replacement poly gate process (RPG)). In a high-k dielectric/metal gate last process, a dummy dielectric and dummy poly gate structure are initially formed, and is followed a typical CMOS process flow until deposition of an inter-level dielectric (ILD). The dummy dielectric and dummy poly gate structure may then be removed and replaced with a high-k gate dielectric/metal gate structure.

The method 100 includes operation 102 in which a semiconductor substrate is provided. The method 100 continues with operation 104 in which a structure is formed over the semiconductor substrate, the structure including a sacrificial dielectric and a dummy gate. In some embodiments, the structure is a gate structure. The method 100 continues with operation 106 in which the sacrificial dielectric and dummy gate are removed from the structure thereby forming a trench. The method 100 continues with operation 108 in which a metal layer is filled into the trench and covering a top surface of an ILD. The method 100 continues with operation 110 in which a chemical mechanical polishing (CMP) is performed and the top surface of the ILD is exposed. The method 100 continues with operation 112 in which the top surface of the ILD is heated. The method 100 continues with operation 114 in which an etch stop layer on the top surface of the ILD is formed.

In FIG. 2A, the semiconductor device 200 includes a semiconductor substrate 201 such as a silicon substrate. In some embodiments, the substrate 201 includes silicon germanium, gallium arsenic, or other suitable semiconductor materials. In some embodiments, the substrate 201 further includes doped regions such as a P-well and/or an N-well (not shown). In some other embodiments, the substrate 201 further includes other features such as a buried layer, and/or an epitaxy layer. Furthermore, in some embodiments, the substrate 201 is semiconductor on insulator such as silicon on insulator (SOI). In other embodiments, the semiconductor substrate 201 includes a doped epi layer, a gradient semiconductor layer, and/or further includes a semiconductor layer overlying another semiconductor layer of a different type such as a silicon layer on a silicon germanium layer. In some other examples, a compound semiconductor substrate includes a multilayer silicon structure or a silicon substrate may include a multilayer compound semiconductor structure. In some embodiments, the substrate 201 may include other elementary semiconductors such as germanium and diamond. In some embodiments, the substrate 201 includes a compound semiconductor such as, silicon carbide, gallium arsenide, indium arsenide, or indium phosphide.

The semiconductor device 200 further includes an isolation structure such as a shallow trench isolation (STI) feature (not shown) formed in the substrate 201 for isolating active regions and of the substrate. In some embodiments, the isolation structure includes a local oxidation of silicon (LOCOS) configuration. The isolation structure includes silicon oxide, silicon nitride, silicon oxynitride, fluoride-doped silicate (FSG), and/or a low k dielectric material known in the art. The active regions include n-type metal-oxide-semiconductor field effect transistors (e.g., NMOSFET or NFET) and p-type metal-oxide-semiconductor field effect transistors (e.g., PMOSFET or PFET). Although only one gate structure is illustrated, it is understood that the semiconductor device 200 may include a number of gate structures for NFETs and PFETs including short channel and long channel transistors.

In FIG. 2A, according to some embodiments of present disclosure, the semiconductor device 200 includes a sacrificial dielectric layer 203 formed on the substrate 201. The sacrificial dielectric layer 203 includes an oxide formed either by thermal or chemical vapor deposition. In some embodiments, the sacrificial dielectric layer 203 is formed in single wafer chamber equipment. In some embodiments, the sacrificial dielectric layer 203 is formed in batch mode furnace. The sacrificial dielectric layer 203 includes a thickness ranging from about 10 to about 100 Angstrom (Å). The semiconductor device 200 also includes a dummy gate 205 formed over the sacrificial dielectric layer 203 by a suitable deposition process. In some embodiments, the dummy gate 205 is formed over the sacrificial dielectric layer 203 by deposition. In some embodiments, silane (SiH4), di-silane (Si2H6), or di-clorsilane (SiCl2H4) may be used as a chemical gas in a chemical vapor deposition (CVD) process to form the dummy gate 205. The dummy gate 205 may include a thickness ranging from about 150 to about 2500 Å.

In some embodiments, the semiconductor device 200 further includes a hard mask layer (not shown) formed on the dummy gate 205. In some embodiments, the hard mask layer includes silicon nitride, silicon oxynitride, silicon carbide, and/or other suitable dielectric materials, and may be formed using a method such as chemical vapor deposition (CVD) or physical vapor deposition (PVD or sputtering). The hard mask layer includes a thickness between about 100 and about 400 Å. In some embodiments, an antireflective coating layer (ARC) is formed on the hard mask layer to enhance a photolithography process for patterning a photoresist layer. For example, a patterned photoresist layer (not shown) may be formed on the hard mask layer. After the patterned photoresist layer is formed, a gate structure 208 (in FIG. 2B) is formed by a dry etch, wet etch, or combination dry and wet etch process. Accordingly, the gate structure 208 may include a sacrificial dielectric layer 203, a dummy gate 205, and a hard mask 207 as shown in FIG. 2B.

After formation of the gate structure (e.g., gate etching or patterning), the semiconductor device 200 undergoes additional CMOS processing to form various features of the NFET and PFET devices as is known in the art. Thus, various features are only briefly discussed herein. In some embodiments, the various features include, lightly doped source/drain regions (n-type and p-type LDD), source/drain (S/D) regions, silicide features, contact etch stop layer (CESL). It should be noted that strained structures such as silicon germanium (SiGe) and silicon carbide (SiC) features may be formed in the PFET and NFET devices, respectively, to boost and enhance the performance of the devices. In some embodiments as in FIG. 2C, sidewall spacers 209, nitride layers 211, and an interlayer dielectric (ILD) 212 are formed.

The ILD layer 212 includes a dielectric material. In some embodiments, the dielectric material includes silicon oxide, silicon nitride, silicon oxynitride, spin-on glass (SOG), fluorinated silica glass (FSG), carbon doped silicon oxide (e.g., SiCOH), BLACK DIAMOND® (Applied Materials of Santa Clara, Calif.), XEROGEL®, AEROGEL®, amorphous fluorinated carbon, Parylene, BCB (bis-benzocyclobutenes), FLARE®, SILK® (Dow Chemical, Midland, Mich.), polyimide, other proper porous polymeric materials, other suitable dielectric materials, and/or combinations thereof. In some embodiments, the ILD layer 212 includes a high density plasma (HDP) dielectric material (e.g., HDP oxide) and/or a high aspect ratio process (HARP) dielectric material (e.g., HARP oxide). The ILD layer 212 includes any suitable thickness. In the present embodiment, ILD layer 212 includes a thickness of about 4000 Å. It is understood that the ILD layer 212 may include one or more dielectric materials and/or one or more dielectric layers. The ILD layer 212 is planarized by a chemical-mechanical-polishing (CMP) process until a top portion of the dummy gate 205 is exposed as illustrated in FIG. 2C. The CMP process includes a high selectivity to provide a substantially planar surface for the dummy gate 205, spacers 209, nitride layers 211, and ILD layer 212. In some embodiments, the CMP process has low dishing and/or metal erosion effect.

In FIG. 2D, a gate replacement process is performed. The dummy gate 205 and the sacrificial dielectric layer 203 are removed by a dry etch, wet etch, combination dry and wet etch, or other suitable process. The dummy gate 205 and sacrificial dielectric layer 203 in FIG. 2C are removed in a single-step etching process or multiple-step etching process. For example, a first wet etch process is used to remove the dummy gate 205. The first wet etch process may include exposure to a hydroxide containing solution (e.g., ammonium hydroxide), deionized water, and/or other suitable etchant solutions. A second wet etch process is used to remove the sacrificial dielectric layer 203. The second wet etch process includes exposure to a buffered HF solution or a buffered oxide etchant (BOE). The second wet etch process may selectively remove the sacrificial dielectric layer 203 and stops at the substrate 201, thereby forming a trench 215 in the gate structure. It is understood that other etching chemicals may be used for selectively removing the dummy dielectric and dummy poly gate.

In FIG. 2E, an interfacial layer 220, high-k dielectric layer 222, and barrier layer 224 are formed to partially fill in the trench 215. The interfacial layer 220 may include a silicon oxide (SiO2) layer (e.g., thermal or chemical oxide formation) having a thickness ranging from about 2 to about 25 Å. In some embodiments, the interfacial layer 220 includes HfSiO or SiON formed by atomic layer deposition (ALD), CVD, PVD, thermal oxidation and nitridation, plasma oxidation and nitridation, or combinations thereof. In some embodiments, an Hf film may be formed on a thermal oxide by ALD, CVD, or PVD, and then oxidized by thermal oxygen to form HfSiO. In other embodiments, an Hf film may be formed by ALD, CVD, or PVD in a reactive oxygen and H2O ambient.

The high-k dielectric layer 222 is formed on the interfacial layer 220. In some embodiments, the high-k dielectric layer 222 is formed by ALD, CVD, metalorganic CVD (MOCVD), PVD, plasma enhanced CVD (PECVD), plasma enhance ALD (PEALD), thermal oxidation, combinations thereof, or other suitable technique. In some embodiments, the high-k dielectric layer 222 includes a thickness ranging from about 5 to about 30 Å. The high-k dielectric layer 222 includes a binary or ternary high-k film such as HfOx. In some embodiments, the high-k dielectric layer 222 includes other high-k dielectrics such as LaO, AlO, ZrO, TiO, Ta2O5, Y2O3, SrTiO3 (STO), BaTiO3 (BTO), BaZrO, HfZrO, HfLaO, HfSiO, LaSiO, AlSiO, HfTaO, HfSiO, (Ba,Sr)TiO3 (BST), Al2O3, Si3N4, oxynitrides, or other suitable materials.

The barrier layer 224 is formed over the high-k dielectric layer 222. In some embodiments, the barrier layer 224 includes TiN or TaN having a thickness ranging from about 5 to about 30 Å. The barrier layer 224 functions as a barrier to protect the high-k dielectric layer 222. The barrier layer 224 is formed by various deposition techniques such as ALD, PVD, CVD, PECVD, or other suitable technique.

In FIG. 2F, a metal layer 230 is formed to fill in a remainder of the trench 215. The metal layer 230 includes any metal material suitable for forming a metal gate or portion thereof, including work function layers, liner layers, interface layers, seed layers, adhesion layers, barrier layers, etc. For example, a P-type work function metal (P-metal) may be formed over the barrier layer 224. The P-metal layer may be formed by ALD, PVD, CVD, or other suitable process. Alternatively, the P-metal layer includes other suitable metals, such as WN, TaN, or Ru, that properly perform in the PFET device. In some embodiments, the P-metal layer includes a multi-metal layer structure such as TiN/WN.

In other embodiments, an N-type work function metal (N-metal) is formed over the barrier layer 224. The N-metal includes TiAl. The N-metal is formed by ALD, PVD, CVD, or other suitable process. In some embodiments, the N-metal layer includes other suitable metals, such as Ti, Ag, Al, TiAlN, TaC, TaCN, TaSiN, Mn, or Zr that perform in the NFET device. Further, a fill metal is deposited over the work function metal layer. For example, a layer of titanium (Ti) is deposited to function as a wetting layer for a subsequent aluminum (Al) fill. The Ti layer is formed by PVD or other suitable process. A layer of Al is formed on the Ti layer to fill in the remainder of the trench 215. The Al layer is formed by forming a first Al layer by CVD and then forming a second Al layer by PVD. In some other embodiments, the fill metal includes tungsten (W), copper (Cu), or other suitable metal material.

A chemical mechanical polishing (CMP) process is performed. In FIG. 2G, a CMP is performed on the metal layer 230 to remove the excess metal material to form a metal gate 232. The CMP has a high selectivity to provide a substantially planar surface for the gate structures 240 (combination of 222, 224, and 232) and ILD layer 212.

In FIG. 2H, a heating process is performed on ILD layer 212 top surface 212a and metal gate structure 240 top surface 240a. The heating process is introduced to remove organic residues on the top surfaces, wherein the organic residues are disposed either from a prior CMP processing or foreign contamination. In some embodiments, the top surfaces are heated in an ambient filled with reduction gases. The reduction gases include, for example, N₂, H₂, NO, NH₃, NH₄, N₂H₂, or other suitable gases. In some embodiments, the ambient has a pressure between about 0.1 mTorr and about 1000 mTorr.

In some embodiments, the substrate 201 is in contact with a heater in order to elevate the temperature of the top surfaces 212a and 240a as in FIG. 2I. The temperature is high enough to break bonding between carbon and oxygen. The carbon is provided by sources such as surfactant or inhibitor in CMP slurry. The temperature is increased to be between about 400 degrees Celsius and about 600 degrees Celsius. Heating duration is between about 10 seconds and 300 seconds. In some embodiments, the top surfaces are heated in a deposition tools, such as a CVD or PVD equipment. The semiconductor device 200 is placed on a top surface 320a of a stage 320 with resistance heater such as a resistor (R) inside. Electric current passes the resistor so as to heat up the stage. The heat generated in the stage 320 is transferred to top surfaces 212a and 240a from the substrate 201.

FIG. 2J is another method of heating the top surfaces 212a and 240a according to some embodiments of present disclosure. The semiconductor device 200 is disposed on holders 332 in a rapid thermal annealing (RTA) chamber. The lamps 326 are used to raise temperature in the chamber through radiation. In some embodiments, the temperature of the top surfaces 212a and 240a is elevated up to 1000 degrees Celsius or to ranges nearing 800-1000 degrees Celsius, while in some other embodiments; the temperature is greater than about 500 degrees Celsius, less than about 800 degrees Celsius. Heating duration is between about 0.1 seconds and about 5.0 seconds. In some embodiments, a process called LTRTA (low temperature rapid thermal annealing) is used to heat up top surfaces 212a and 240a. In some embodiments, top surfaces 212a and 240a are heated in RTA chamber with reduction gas comprising N₂, H₂, NO, NH₃, NH₄, N₂H₂.

In some embodiments, the heating process is conducted in a furnace filled with reduction gases such as N₂, H₂, NO, NH₃, NH₄, N₂H₂, or other suitable gases. In some embodiments, the heating process is conducted in a module installed in a CMP tool which is used to perform operation 110 in FIG. 1. The module is equipped with a lamp heating device to raise temperature of the top surfaces 212a and 240a after slurry removal.

The semiconductor device 200 may undergo further including dielectric material disposed on the top surfaces 212a and 240a after a heating operation. As in FIG. 2K, a dielectric film 246 is disposed over the substrate 201 to cap the top surfaces 212a and 240a. The dielectric 246 can be a single film or a stack as in FIG. 2K to include an etch stop layer 246a and a capping layer 246b. In some embodiments, the dielectric 246 is formed of oxide, nitride, oxynitride, and low k dielectrics comprising carbon-based, Si-based layers formed by PECVD, SOG or SOD, or combinations thereof. Dielectric 246 and ILD 212 may be formed of a same material or different materials. The dielectric 246 and ILD 212 in combined is also called a composite ILD.

In some embodiments, top surfaces 212a and 240a are heated in a chamber configured for forming etch stop layer 246a. It is also called an in-situ heating operation. For example, the semiconductor device 200 is disposed on a stage in a CVD process chamber used to deposit the etch stop layer 246a. A heating operation as in FIG. 2I is conducted before the CVD process. A heating operation with a duration of about 10 to 30 seconds is introduced in combined with some reduction gases such as N₂, H₂, NO, NH₃, NH₄, N₂H₂, or other suitable gases. Top surfaces 212a and 240a are heated to a temperature ranges nearing about 400 to about 600 degrees Celsius. There is no any reactive gas is allowed at the heating operation until the heating operation is completed.

A contact hole 250 is formed in the composite ILD by an etch process as in FIG. 2L. The etch process may use any suitable etching method including, for example, a plasma dry etch, a chemical wet etch, or other processes. For example, the etch process is performed in a dry etching device, using a mixed gas of He, Ar, O2, CF based gases, NF3 and SF6 under the conditions of a gas pressure of 5-50 mTorr and an RF bias power of 1000-2500 W. After the etch process is completed, photoresist layer (not shown) is stripped. In some embodiments, the etch process is performed in a dry etching device, using a mixed gas of He, Ar, O2, CF based gases, NF3 and SF6 under the conditions of a gas pressure of 5-10 mTorr and an RF bias power of 1000-2500 W. After the etch process is completed, photoresist layer (not shown) is stripped.

A nickel silicide layer, NiSiₓ, 256 is formed in the contact hole 250 as in FIG. 2M. The nickel silicide herein are often nonsoichiometric, thus a subscript “x” for the silicon composition is used in the present disclosure. Preparation for nickel silicide formation is via formation of a thin, titanium layer. The presence of titanium underlying a subsequently deposited nickel layer, allows the anneal procedure used to form metal silicide to be performed at a temperature in which nickel silicide will not agglomerate or become unstable. However to be effective in reducing nickel silicide instability during the metal silicide formation anneal procedure the titanium interlayer is maintained at a minimum thickness of between about 10 to 15 Angstroms, with excellent thickness uniformity. To insure the uniformity of the thin, titanium interlayer, an atomic layer deposition (ALD) procedure is employed to form titanium interlayer, at a thickness between about 10 to 15 Angstroms, with the ALD procedure providing the desired titanium comformality and thickness uniformity.

Nickel layer, is next formed via physical vapor deposition (PVD) procedures such as RF sputtering or evaporation, at a thickness between about 50 to 500 Angstroms. An initial phase of an RTA procedure is next performed a temperature between about 250 to 700° degrees Celsius, resulting in the formation of an annealed layer, wherein the annealed layer is comprised of only nickel and incorporated titanium interlayer component. Continuation of the RTA procedure, again performed at a temperature between about 250 to 700° degrees Celsius, results in the formation of nickel silicide region, Portions of nickel silicide region remain unreacted.

Removal of unreacted nickel silicide, the nickel-titanium layer, is next selectively accomplished via wet etch procedures using a mixture comprised of H2SO4-H2O2-HCl—NHOH4-H3PO4-HNO3-CH3COOH—. The nickel silicide layer, NiSiₓ, 256 is finally formed. It should be noted that this procedure, the use of a thin titanium interlayer for nickel silicide formation, can also be applied to formation of other metal silicide layers, such as cobalt silicide. A remaining portion of the contact hole 250 is subsequently filled with conductive material to form a contact plug. The contact plugs includes, for example, tungsten, copper, or aluminum.

An advantage of the present disclosure is to develop a robust film adhesion between the top surfaces 212a and the etch stop layer 246a. Because organic residues on the top surfaces 212a and 240a are removed by a heating operation before dielectric 246 is disposed thereon, the adhesion between the dielectric 246 and the ILD 212 located underneath is improved. Interface of etch stop layer 246a and the ILD 212 is more resistant to lateral etch during silicide formation. The mixture of wet etch used to remove unreacted metal silicide can not penetrate into the interface and further attack the top surface 230a of the metal gate structure.

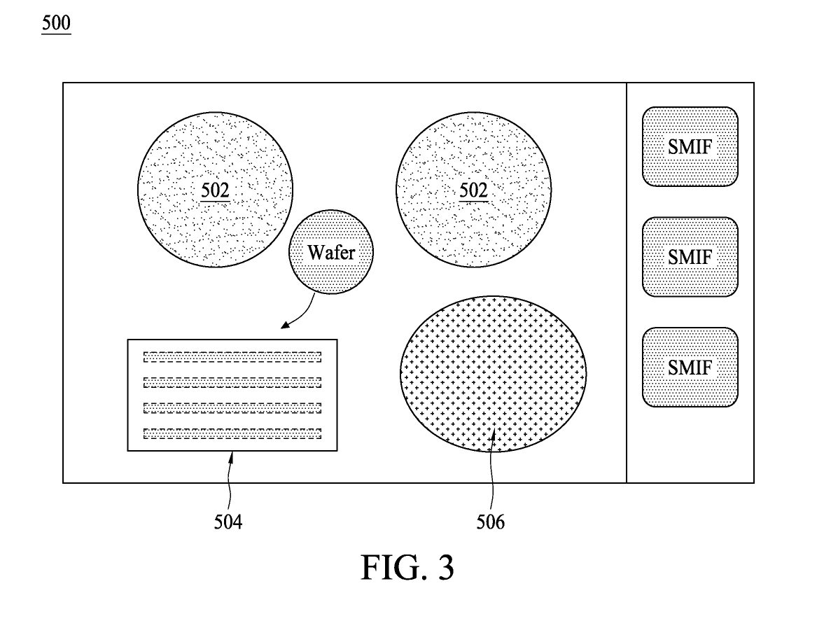

FIG. 3 is a semiconductor wafer chemical mechanical polishing apparatus 500 in accordance with some embodiments of the present disclosure. The semiconductor wafer chemical mechanical polishing apparatus 500 has a chemical mechanical polish module 502, a clean module 504, and a heating module 506. A semiconductor wafer (not depicted) is conveyed between the chemical mechanical polish module 502, the clean module 504, and the heating module 506 by a conveyer.

In some embodiments in accordance with the present disclosure, the chemical mechanical polish module 502 is configured to chemically mechanically polish a film on the semiconductor wafer. For example, a metal layer 230 as shown in FIG. 2F. The polishing process is designed to remove the surface topologies and smoothes and flattens the surface of the semiconductor wafer. The polish module 502 includes a polishing pad, a pad conditioner, a slurry dispenser. A polish head is configured to push the semiconductor wafer against the polishing pad. The polishing pad is configured to create mechanical abrasion and chemical etch to the semiconductor wafer.

The clean module 504 is configured to clean the residues on the semiconductor wafer surface from the CMP process. The clean module 504 is configured to remove the residual slurry particles and other chemical contaminants introduced during the chemical mechanical polishing process by the slurries, the polishing pad, and the pad conditioner.

In some embodiments, the apparatus 500 further has a dryer (not shown) configured to dehydrate semiconductor wafer surface after cleaning. In certain embodiments, the dryer is configured to spin-dry the semiconductor wafer. In some embodiments, the dryer is an IPA (isopropyl alcohol) dryer.

The heating module 506 is installed as in-situ unit in the CMP apparatus 500. Wafers after CMP operation are transferred into the heating module 506 in order to get polished surface heated. The heating module 506 includes different configurations, for example, a heating chamber with a stage and the stage has an embedded resistance heater inside, an RTA chamber, a heating lamp, an infrared (IR) wave heater. The heating module 506 is designed to raise temperature of the polished wafer surface to predetermined degrees Celsius as required by the abovementioned various embodiments.

A method of manufacturing a semiconductor device includes providing a semiconductor substrate and forming a structure over the semiconductor substrate. The structure includes a sacrificial dielectric on the semiconductor substrate and a dummy gate over the sacrificial dielectric. The method further includes removing the dummy gate and the sacrificial dielectric from the structure thereby forming a trench. The method further includes filling a metal layer into the trench and covering over a top surface of an inter layer dielectric (ILD). The method also includes performing a chemical mechanical polishing (CMP) to expose the top surface of the ILD and heating the top surface of the ILD. Moreover, the method includes forming an etch stop layer on the top surface of the ILD.

In some embodiments, the heating the top surface of the ILD is performed in a tool configured for performing a chemical mechanical polishing (CMP) to expose the top surface of the ILD.

In some embodiments, the method includes heating the top surface of the ILD is under a temperature between about 400 degrees Celsius and 600 degrees Celsius.

In some embodiments, the method includes introducing a reduction gas comprising N₂, H₂, NO, NH₃, NH₄, N₂H₂ while heating the top surface of the ILD.

A method of manufacturing a semiconductor device includes providing a semiconductor substrate and forming a gate structure over the substrate, wherein the gate structure included a first spacer and a second spacer. The method further includes forming a trench between the first spacer and the second spacer and filling the trench with a metal layer. In some embodiments, the method also has operations of performing a chemical mechanical polishing (CMP) to remove a portion of the metal layer and form a metal gate thereby exposing a top surface of an inter layer dielectric (ILD). In some embodiments, the method includes heating a top surface of the metal gate and the top surface of the ILD; and forming an etch stop layer over the metal gate and the ILD.

In some embodiments, heating a top surface of the metal gate and the top surface of the ILD is conducted in a CVD chamber, a furnace, an RTA chamber. In some embodiments, heating a top surface of the metal gate and the top surface of the ILD is by lamps heating, IR wave heating. In some embodiments, heating a top surface of the metal gate and the top surface is in a substantially oxygen-free environment.

An apparatus of manufacturing a semiconductor device includes a semiconductor wafer polish module configured to remove a metal material from a top surface of a semiconductor wafer and a clean module arranged to clean the semiconductor wafer after being polished in the semiconductor wafer polish module. The apparatus further includes a heating module configured for heating the top surface of the semiconductor wafer.

An apparatus of manufacturing a semiconductor device includes an IPA tank configured to dehydrate the semiconductor wafer after clean.

An apparatus of manufacturing a semiconductor device includes a stage configured to hold the semiconductor wafer and a heater inside the stage.

An apparatus of manufacturing a semiconductor device includes a heating module having a heating lamp, an RTA.

Although the present invention and its advantages have been described in detail, it should be understood that various changes, substitutions and alterations cancan be made herein without departing from the spirit and scope of the invention as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of manufacturing a semiconductor device, comprising:
providing a semiconductor substrate;
forming a structure over the semiconductor substrate, the structure including a sacrificial dielectric on the semiconductor substrate and a dummy gate over the sacrificial dielectric;
removing the dummy gate and the sacrificial dielectric from the structure thereby forming a trench;
filling a metal layer into the trench and covering over a top surface of an inter layer dielectric (ILD);
performing a chemical mechanical polishing (CMP) to expose the top surface of the ILD;
heating the top surface of the ILD; and
forming an etch stop layer on the top surface of the ILD.

2. The method of claim 1, wherein the heating the top surface of the ILD is in a chamber configured for forming the etch stop layer on the top surface of the ILD.

3. The method of claim 1, wherein the heating the top surface of the ILD is in a tool configured for performing a chemical mechanical polishing (CMP) to expose the top surface of the ILD.

4. The method of claim 1, wherein the heating the top surface of the ILD is to a temperature ranges nearing about 400 degrees Celsius to about 600 degrees Celsius.

5. The method of claim 1, wherein the heating the top surface of the ILD is in a rapid thermal annealing (RTA).

6. The method of claim 1, wherein the heating the top surface of the ILD includes introducing a reduction gas comprising N₂, H₂, NO, NH₃, NH₄, N₂H₂.

7. The method of claim 1, wherein the heating the top surface of the ILD is under a pressure between about 0.1 mTorr and 1000 mTorr.

8. The method of claim 1, wherein the heating the top surface of the ILD is performed for about 10 seconds to 300 seconds.

9. The method of claim 1, wherein the heating the top surface of the ILD further comprising disposing the semiconductor device on a top surface of a stage, wherein the stage has a resistance heater inside.

10. A method of manufacturing a semiconductor device, comprising:
providing a semiconductor substrate;
forming a gate structure over the substrate, the gate structure including a first spacer and a second spacer;
forming a trench between the first spacer and the second spacer;
filling the trench with a metal layer;
performing a chemical mechanical polishing (CMP) to remove a portion of the metal layer and form a metal gate thereby exposing a top surface of an inter layer dielectric (ILD);
heating a top surface of the metal gate and the top surface of the ILD; and
forming an etch stop layer over the metal gate and the ILD.

11. The method of claim 10, wherein the top surface of the metal gate and the top surface of the ILD are substantially coplanar after the heating a top surface of the metal gate and the top surface of the ILD.

12. The method of claim 10, wherein the heating a top surface of the metal gate and the top surface of the ILD includes lamp heating.

13. The method of claim 10, wherein the heating a top surface of the metal gate and the top surface of the ILD is performed by an RTA with a reduction gas comprising N₂, H₂, NO, NH₃, NH₄, N₂H₂.

14. The method of claim 13, wherein the RTA is performed under a temperature up to 1000 degrees Celsius.

15. The method of claim 13, wherein the RTA is performed for about 0.1 seconds and about 5 seconds.

16. The method of claim 10, wherein the heating a top surface of the metal gate and the top surface of the ILD is performed is in a substantially oxygen-free environment.

17. An apparatus of manufacturing a semiconductor device, comprising:
a semiconductor wafer polish module configured to remove a metal material from a top surface of a semiconductor wafer;
a clean module arranged to clean the semiconductor wafer after being polished in the semiconductor wafer polish module; and
a heating module configured for heating the top surface of the semiconductor wafer.

18. The apparatus of claim 17, further comprising an IPA tank configured to dehydrate the semiconductor wafer after clean.

19. The apparatus of claim 17, wherein the heating module includes a stage configured to hold the semiconductor wafer and a heater inside the stage.

20. The apparatus of claim 17, wherein the heating module comprises a heating lamp, an RTA.
